(19) United States
(12) Patent Application Publication
(10) Pub. No.: US 2009/0020155 A1
(43) Pub. Date: Jan. 22, 2009

(54) Silicon multiple solar cell and method for production thereof

(76) Inventors: Walter Frammelsberger, Neuoetting (DE); Peter Lechner, Vaterstetten (DE)

Correspondence Address: FLYNN THIEL BOUTELL & TANIS, P.C., 2026 RAMBLING ROAD, KALAMAZOO, MI, 49008-1631, US

(21) Appl. No.: 12/217,572

(22) Filed: Jul. 7, 2008

(30) Foreign Application Priority Data
Jul. 18, 2007 (DE) 10 2007 033 444.5

(51) Int. Cl. H01L 31/00

(52) U.S. Cl. 136/255

(57) ABSTRACT

A silicon multiple solar cell has at least two subcells (1, 2) each having a p-type layer (p1, p2), an intrinsic layer (i1, i2) and a phosphorus-doped n-type layer (n1, n2). The p-type layer (p2) which is in contact with the n-type layer (n1) of the subcell (1) disposed therebefore is configured to be at least partly nano- or microcrystalline.

This invention relates to a silicon multiple solar cell according to the preamble of claim 1 and to a method for production thereof.

Silicon solar cells generally have the layer sequence p-i-n, i.e. a p-type layer or p-layer, an intrinsic layer or i-layer and an n-type layer or n-layer, an electric field being produced over the whole i-layer. Multiple cells comprising subcells each having a p-i-n layer sequence permit the electric field to be substantially enlarged.

For producing the multiple cells it is common to use chemical vapor deposition (CVD), in particular the plasma enhanced (PE) CVD process.

The layers of the individual subcells are produced by fractionating silicon-containing gases in the plasma. The deposition gas employed is usually silane (SiH₄) or disilane (Si₂H₆). Besides the (undoped) i-layers, the doped p- and n-layers are deposited, namely, the p-layers through which light falls into the i-layers, normally by addition of boron, in particular by admixture of diborane (B₂H₆) or trimethylboron (B(CH₃)₃) to the deposition gas, and the n-layer by addition of phosphorus, for example by admixture of phosphine to the deposition gas.

For an economical production of silicon multiple solar cells it has proved especially suitable to use in particular the single-chamber process, by which the deposition of all layers of the multiple solar cell is effected in the layer sequence p-i-n-p-i-n in succession in one and the same reactor, that is, without the reactor being cleaned between the deposition of the doped and intrinsic layers. Thus, in the PECVD process the deposition of the individual layers can be carried out without transport of the substrate or also without interruption of the plasma.

Due to the fast deposition rate, p-, i- and n-layers are preferably deposited from amorphous silicon.

The quality of a silicon multiple solar cell of the p-i-n type is determined substantially by the quality of the intrinsic layers. It is therefore necessary to keep the defect density of the intrinsic layers of a silicon multiple solar cell as low as possible.

It is therefore the object of the invention to substantially reduce the defect density of the intrinsic layers of a silicon multiple solar cell.

This is achieved according to the invention by the silicon multiple solar cell characterized in claim 1. Claims 2 to 6 render advantageous embodiments of the invention.

The inventive silicon multiple solar cell comprises at least two subcells each comprising a p-layer, an i-layer deposited thereon, and a phosphorus-doped n-layer deposited on the i-layer.

The invention is based on the observation that, besides the defects caused by unsaturated bonding electrons, in particular unintentional doping leads to defects of the intrinsic layers. This danger exists in particular with the single-chamber process since doping elements can thereby be spread from the previously deposited doped layers into the intrinsic layers. Possible sources are e.g. insufficiently bound doping elements which are deposited on the reactor walls and in the PECVD process also on the electrode of the PECVD reactor in the single-chamber process in the same manner as the multiple cell on the substrate.

An essential part is played here in particular by the spreading of the phosphorus required for doping the n-layers.

It was now observed according to the invention that the spreading of phosphorus into the intrinsic layers can be largely ruled out if the p-layer of the second or each further subsequent subcell deposited on the phosphorus-doped n-layer of the first or previous subcell is configured to be at least partly nano- or microcrystalline. Nano- or microcrystalline silicon is understood here to mean a silicon comprising crystals with a size of 1 nm to 1 μm, in particular 10 to 100 nm.

The inventive solar cell can be e.g. a tandem cell with two subcells or a triple cell with three subcells, each with a p-i-n layer sequence, the light falling through the p-layer into the intrinsic layer of the particular subcell.

The production of the inventive silicon multiple solar cell is preferably effected by CVD in a single-chamber process, i.e. the deposition in the layer sequence p-i-n of the first subcell and each further subcell is effected by CVD in one and the same reactor. It is preferable to carry out the PECVD process.

The deposition gas used is preferably silane, disilane or another silane hydrogen gas, whereby the deposition gas can have hydrogen (H₂) or noble gases admixed thereto. The plasma for fractionating the gases in the PECVD process can be produced by applying a direct voltage or alternating voltage. The frequency domains for the electrical alternating field extend from the low-frequency kilohertz range through radio frequencies in the MHz range to microwaves in the GHz range. It is preferable to use an electrical alternating field with a frequency in the range of 1 to 100 MHz.

To configure the p-layer which is in contact with the n-layer of the previously deposited subcell to be at least partly nano- or microcrystalline, a deposition gas with a high content of hydrogen (H₂) is used to form reactive hydrogen atoms in the deposition gas. It is also usual to increase the gas pressure, and in a PECVD process with an electrical alternating field the frequency for activating the hydrogen in the deposition gas.

The at least partly nano- or microcrystalline p-layer which according to the invention is in contact with the previously deposited n-layer of the subcell disposed therebefore in the direction of incident light constitutes a barrier layer which prevents spreading of phosphorus from the previously deposited n-layer.

The intrinsic layers of the inventive multiple solar cell preferably comprise amorphous silicon which is deposited considerably faster than nano- or microcrystalline silicon.

The n-layer which is in contact with the p-layer of the subsequent subcell can comprise amorphous silicon, but the n-layer preferably has a sublayer of nano- or microcrystalline silicon on the interface with the p-layer, while the remaining part of the n-layer is amorphous. This makes it possible to obtain a low series resistance on the n/p contact and thus a high fill factor in the solar cell.

The p-layer which is in contact with the n-layer of the subcell disposed therebefore can comprise nano- or microcrystalline silicon completely. However, it is preferable for only a sublayer of the p-layer to be nano- or microcrystalline while the remaining part is amorphous in order to deposit the p-layer faster.

It is in this case preferable for the sublayer of the p-layer to be nano- or microcrystalline on the interface with the n-layer while the remaining part of the p-layer is amorphous. The nano- or microcrystalline sublayer of the p-layer on the interface with the n-layer reduces the series resistance on the n/p contact and thus increases the fill factor.

That is, an inventive multiple cell preferably comprises e.g. the following layer sequence: amorphous p-layer, amorphous i-layer, amorphous n-layer or amorphous n-sublayer, nano- or microcrystalline n-sublayer as the first subcell and nano- or microcrystalline p-sublayer, amorphous p-sublayer, amorphous i-layer, amorphous n-layer as the last subcell, whereby further subcells between the first and last subcells preferably each comprise the following layer sequence: a nano- or microcrystalline p-sublayer, an amorphous p-sublayer, an amorphous i-layer and an amorphous n-layer or an amorphous n-sublayer and a nano- or microcrystalline n-sublayer.

The layer thickness of the p-layer which is in contact with the n-layer of the subcell disposed therebefore is in total preferably 5 to 30 nm, in particular 8 to 10 nm. The nano- or microcrystalline sublayer of the p-layer preferably has here a layer thickness of at least 2 nm, in particular 3 to 5 nm.

The layer thickness of the n-layer which is in contact with the p-layer of the subsequent subcell is preferably 5 to 30 nm, in particular 8 to 15 nm.

The p-type layer which is in contact with the n-type layer of the previously disposed subcell is preferably alloyed with carbon, oxygen or nitrogen, optionally also a mixture of said elements, in order to increase the band-gap.

For this purpose it is possible during production of the p-layer to admix a gas containing said elements to the deposition gas. This reduces the light absorbance of the p-layer through which light falls into the intrinsic layer.

While the doping of the n-layers is carried out with a phosphorous gas, in particular phosphine, which is admixed to the deposition gas, the p-layers are normally produced by admixture of diborane or trimethylboron to the deposition gas.

Otherwise the inventive silicon multiple solar cell corresponds to the prior art, i.e. it has, as usual, a transparent electrode layer on the front p-layer of the first subcell on the light incidence side and an electrode layer on the back n-layer, further for example a transparent carrier plate on the light incidence side which generally at the same time constitutes the substrate for depositing the multiple solar cell.

The attached drawing shows:

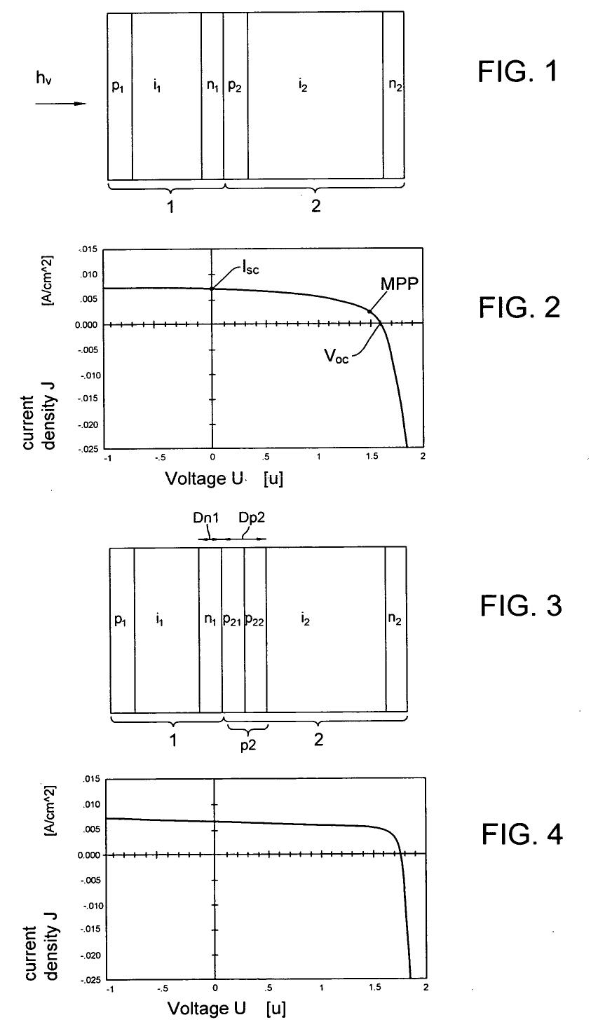

FIG. 1 the schematic structure of a usual silicon tandem cell;

FIG. 2 a diagram with the characteristic of a usual tandem cell according to Example 1 below;

FIG. 3 the schematic and exemplary structure of an inventive silicon tandem cell; and

FIG. 4 a diagram with the characteristic of the inventive tandem cell according to Example 2.

According to FIG. 1, the conventional silicon tandem cell has a first subcell 1 on which light falls, and a second subcell 2. The first and second subcells 1, 2 are each configured as a p-i-n cell, i.e. they each have on the front, i.e. light incidence, side a p-layer p1, p2 and on the back side an n-layer n1, n2, whereby the n-layer n1 of the first subcell 1 and the p-layer p2 of the second subcell 2 are in contact with each other. Between the p-layers p1, p2 and the n-layers n1, n2 of each subcell 1, 2 there is provided in each case an intrinsic layer or i-layer i1, i2. The p-layers p1, p2 and the intrinsic layers i1, i2 each comprise amorphous silicon, as do the n-layers n1, n2.

The inventive tandem cell according to FIG. 3 differs from that in FIG. 1 substantially in that the p-layer p2 of the second subcell 2 which is in contact with the n-layer n1 of the first subcell 1 comprises a first sublayer p21 of nano- or microcrystalline silicon which is in contact with the n-layer n1 of the first subcell 1, as well as a second sublayer p22 of amorphous silicon which is in contact with the intrinsic layer i2 of the second subcell 2. Further, the p-layer p2 of the second subcell 2 which is in contact with the n-layer n1 of the first subcell 1 has a greater layer thickness Dp2 relative to the layer thickness Dn1 of the n-layer n1.

### EXAMPLE 1

### Comparison

There was produced a usual silicon tandem solar cell according to FIG. 1 in a single-chamber process by PECVD in an electrical alternating field (frequency 13.56 MHz). The layer thickness of the carbon-alloyed, boron-doped amorphous p-layers p1 and p2 is in each case 8 nm, of the phosphorus-doped amorphous n-layers n1 and n2 in each case 10 nm, and of the amorphous intrinsic layers i1 and i2 in each case 300 nm.

FIG. 2 shows the characteristic of the tandem solar cell. MPP represents the maximum power point, I_{SC} the short-circuit current, and V_{OC} the open-circuit voltage.

The fill factor is 53%. By secondary ion mass spectrometry (SIMS) there was detected a phosphorus concentration of more than 1×10⁸ cm⁻³ at the beginning of the intrinsic layer i2 of the second subcell 2.

### EXAMPLE 2

Example 1 was repeated except that a tandem solar cell was produced whose n-layer n1 of the first subcell 1 had a layer thickness of 5 nm, whereby the front p-layer p2 of the second subcell 2 at the interface with the n-layer n1 of the first subcell 1 comprised a first sublayer p21 of nano- or microcrystalline silicon with a layer thickness of 5 nm, as well as an adjacent second sublayer p22 of amorphous silicon with a layer thickness of 8 nm.

FIG. 4 shows the characteristic of the tandem solar cell. It has a fill factor of 76%.

1. A silicon multiple solar cell comprising at least two subcells (1, 2) each having a p-type layer (p1, p2), an intrinsic layer (i1, i2) and a phosphorus-doped n-type layer (n1, n2), the light falling through the p-type layer (p1, p2) into the intrinsic layer (i1, i2) of the particular subcell (1, 2), and the p-type layer (p2) having a first sublayer (p21) at the interface with the n-type layer (n1) of the subcell (1) disposed therebefore, and a second, amorphous sublayer (p22), characterized in that the first sublayer (p21) of the p-type layer (p2) comprises nanocrystalline silicon comprising crystals with a size of 1 to 100 nm and has a layer thickness of at least 2 nm, and the n-type layer (n1) has a smaller layer thickness (Dn2) than the layer thickness (Dp2) of the p-type layer (p2,) in contact therewith, of the subsequent subcell (2).

2. The silicon multiple solar cell according to claim 1, characterized in that the intrinsic layers (i1, i2) comprise amorphous silicon.

3. The silicon multiple solar cell according to claim 1, characterized in that the n-type layer (n1) which is in contact with the p-type layer (p2) of the subsequent subcell (2) is configured to be at least partly amorphous.

4. The silicon multiple solar cell according to claim 3, characterized in that the n-type layer (n1) has an amorphous sublayer and at the interface with the p-type layer (p2) of the subsequent subcell (2) a nano- or microcrystalline sublayer.

5. The silicon multiple solar cell according to claim 1, characterized in that the n-type layer (n1) which is in contact with the p-type layer (p2) of the subsequent subcell (2) has a layer thickness of 20 nm or less.

6. The silicon multiple solar cell according to claim 1, characterized in that the p-type layer (p2) which is in contact with the n-type layer (n1) of the subcell (1) disposed therebefore has an increased band-gap by alloying with carbon, oxygen or nitrogen.
